(19) United States
(12) Patent Application Publication
(10) Pub. No.: US 2009/0047510 A1
(43) Pub. Date: Feb. 19, 2009

(54) Coated product and method of production thereof

(76) Inventors: Mikael Schuisky, Sandviken (SE); Jen-Petter Palmquist, Vasteras (SE)

Correspondence Address: DRINKER BIDDLE & REATH (DC), 1500 K STREET, N.W., SUITE 1100, WASHINGTON, DC, 20005-1209, US

(21) Appl. No.: 11/664,495

(22) PCT Filed: Nov. 28, 2005
(86) PCT No.: PCT/SE2005/001792

§ 371 Date: Apr. 21, 2008

(30) Foreign Application Priority Data
Nov. 26, 2004 (SE) 0402904-7

(51) Int. Cl. B32B 15/04; C23C 16/22; C23C 14/34; C23C 14/35

(52) U.S. Cl. 428/337; 427/249.15; 427/249.18; 427/249.19; 427/249.17; 427/248.1; 204/192.15; 428/457

(57) ABSTRACT

A coated product is disclosed consisting of a metallic substrate and a composite coating wherein at least one component of the composite coating is of MAX material type. Furthermore, a method of producing such a coated product is disclosed using vapour deposition technique in a continuous roll to roll process.

The present disclosure relates to a coated product, which consists of a metallic substrate and a composite coating containing so called MAX material. Furthermore, the present disclosure relates to the manufacturing of such a coated product.

### BACKGROUND AND PRIOR ART

A MAX material is a ternary compound with the following formula Mₙ₊₁A_{z}Xₙ. M is at least one transition metal selected from the group of Ti, Sc, V, Cr, Zr, Nb, Ta; A is at least one element selected from the group consisting of Si, Al, Ge and/or Sn; and X is at least one of the non-metals C and/or N. The ranges of the different components of the single phase material is determined by n and z, wherein n is within the range of 0.8-3.2 and z is within the range of 0.8-1.2. Consequently, examples of compositions within the MAX material group are Ti₃SiC₂, Ti₂AlC, Ti₂AlN and Ti₂SnC.

MAX materials may be used in several different environments. These materials have a good electrical conductivity, are high temperature resistant, have high corrosion resistance as well as low friction and are relatively ductile. Some MAX materials are also known to be bio-compatible. Consequently, MAX materials and coatings of MAX materials on metallic substrates are well suited for use as for example electrical contact materials in corrosive environments and at high temperatures, wear resistant contact materials, low friction surfaces in sliding contacts, interconnects in fuel cells, coatings on implants, decorative coatings and non-sticking surfaces, just to name a few.

It is previously known to accomplish articles coated with MAX materials in batch processes, see for example WO 03046247 A1. However, such processes do not produce a cost effective material and uses fairly advanced technology by for example utilising a seed layer. Therefore, there is a need of a process to produce a cost effective substrate material with a dense coating of MAX material.

In some cases it might be needed to enhance the properties of the MAX material, for example a higher electrical conductivity, lower contact resistance and/or enhanced wear resistance.

Consequently, the present disclosure relates to the process of manufacturing a substrate coated with a composite coating containing MAX material in a cost effective manner while at the same time accomplishing a dense coating with a good adhesion to the substrate.

It is a further object of the invention to enhance at least one property of the MAX material, preferably the electrical conductivity, in a simple manner during a cost effective manufacturing process.

### DETAILED DESCRIPTION

A substrate coated with a composite material containing MAX material is produced in a continuous roll-to-roll process while achieving a good adhesion of the coating over the total surface of the substrate. In this context a good adhesion is considered to mean that the product is able to be bent at least 90 degrees over a radius equal to the thickness of the substrate without showing any tendency to flaking, spalling or the like, of the coating.

The composition of the substrate material could be any metallic material. According to an embodiment the substrate material is selected from the group consisting of Fe, Cu, Al, Ti, Ni, Co and alloys based on any of these elements. Some examples of suitable materials to be used as substrates are ferritic chromium steels of the Type AISI 400-series, austenitic stainless steels of the type AISI 300-series, hardenable chromium steels, duplex stainless steels, precipitation hardenable steels, cobalt alloyed steels, Ni based alloys or alloys with a high content of Ni, and Cu based alloys. According to a preferred embodiment, the substrate is a stainless steel with a chromium content of at least 10% by weight.

The substrate may be in any condition, such as soft annealed, cold-rolled or hardened condition as long as the substrate is able to withstand the coiling on the rolls of the production line.

The substrate is a metallic substrate material in the form of a strip, foil, wire, fibre, tube or the like. According to a preferred embodiment the substrate is a in the form of a strip or foil.

The substrate could have any dimension. However, a length of the substrate of at least 10 meters ensures a cost effective coated product. According to an embodiment the length is at least 50 meters. According to another embodiment the length of the substrate is at least 100 meters. In fact, the length might be up to at least 20 km, and for certain product forms such as fibres, it might be even much longer.

The thickness of the substrate when in the form of a strip or foil is usually at least 0.015 mm thick, preferably at least 0.03 mm, and up to 3.0 mm thick, preferably maximally 2 mm. The most preferred thickness is within the range of 0.03-1 mm. The width of the strip is usually between 1 mm and 1500 mm. However, according to an embodiment the width is at least 5 mm, but at the most 1 m.

The coating is a composite coating containing at least two separate components wherein at least one is a MAX material. The coating may also contain further components. A component is in this context considered to mean a phase, a structure, a compound or the like. The microstructure of the composite coating could be a single multi-component layer or it could be a multilayer coating of different components or any combination of those.

The composition of the MAX material of the composite is Mₙ₊₁A_{z}Xₙ. M is at least one transition metal selected from the group of Ti, Sc, V, Cr, Zr, Nb, Ta; A is at least one element selected from the group consisting of Si, Al, Ge and/or Sn; and X is at least one of the non-metals C and/or N. The ranges of the different components of the single phase material is determined by n and z, wherein n is within the range of 0.8-3.2 and z is within the range of 0.8-1.2.

The crystallinity of the MAX material in the composite coating may vary from amorphous or nanocrystalline to well crystallised and near single phase material. The different crystallographic forms can be accomplished by control of temperature or other process parameters during growth of the coating, i.e. during deposition. For example, a higher temperature during deposition of the coating may render a coating of a higher crystallinity.

As mentioned above, the composite contains at least one component in addition to the MAX material. The component may be any component that enhances the property to be optimised. For example, if the property to be enhanced is the electrical conductivity, the other component of the composite coating may for example be a metal, such as Ag, Au, Cu, Ni, Sn, Pt, Mo or Co. However, it might also be other elements, such as a non-metal like C. Another example is in the case the property to enhance is the wear resistance wherein the other component of the composite coating might for example be TiC, TiN or Al₂O₃. According to one embodiment, the coating contains at least two different MAX materials.

The amount of MAX material in the coating may vary largely depending on the intended application of the coated product, i.e. the ratio between the components of the composite can be varied to achieve the right desired properties of the coating, such as wear, conductivity and/or corrosion resistance. However, according to an embodiment the composite coating is based on the MAX material, i.e. the content per volume of MAX material is higher than the content of each of the other components of the coating. According to another embodiment, the content of MAX material of the composite is at least 70% by volume; preferably, the content of MAX material of the composite is at least 90% by volume. According to yet another embodiment, the composite coating merely contains smaller amounts of MAX materials, i.e. less than 20% by volume, preferably less than 10% by volume.

The coating has a thickness adapted to the usage of the coated product. According to an embodiment the thickness of the composite coating is at least 5 nm, preferably at least 10 nm; and not more than 25 μm, preferably not more than 10 μm, most preferably not more than 5 μum. Suitable thicknesses usually falls within the range of 50 nm -2 μm.

The substrate may be provided with the composite coating by any method resulting in a dense and adherent coating, for example electrochemical deposition or vapour deposition. However, in order to produce a cost effective coated product the coating is performed using vapour phase deposition technique in a continuous roll to roll process. The vapour deposition process could be a PVD process such as magnetron sputtering or electron beam evaporation. The electron beam evaporation process can be both plasma activated and/or reactive if needed, in order to form a dense and well adherent layer. The composite coating may be produced in steps by utilising several deposition chambers in line, but it may also be produced in one single chamber.

Naturally, the surface of the substrate is preferably cleaned in a proper way before coating, for example to remove oil residues and/or the native oxide layer of the substrate.

One advantage of the use of PVD technique is that the substrate material is not heated as much as would be required during for example a CVD process. Consequently, the risk of deterioration of the substrate material during coating is reduced. Deterioration of the substrate may be further prevented with the aid of controlled cooling of the substrate during coating.

When utilising a continuous coating process, the substrate speed during coating is at least 1 meters/minute. According to an embodiment the substrate speed is at least 3 meters/minute and in certain cases at least 10 meters/minute. The high speed ensures a cost effective production of the coated product. Furthermore, a high speed also reduces the risk of deterioration of the substrate material whereby a higher quality of the product may be achieved.

In the case where the substrate is a strip or foil it may be provided with a coating on one side or on both sides. In the case the coating is provided on both surfaces of the strip, the composition of the coatings on each side of the strip may be the same but may also differ depending on the application in which the coated product will be used. The strip may be coated on both sides simultaneously or on one side at a time.

The MAX phase of the composite coating may for example be produced by vaporising a target of a MAX material and depositing onto the substrate according to the definition stated above.

The MAX phase containing composite coating may for example be produced by vaporising a target consisting of at least two parts wherein one is a MAX material and the other is the at least one other component of the composite, which could for instance be one of the following metals Ag, Au, Ni, Cu, Sn, Pt, Mo, Co or an alloy based thereof. Another possible manufacturing process is by utilising a target of a MAX material in one deposition chamber and in another deposition chamber coat with the at least one other component of the coating.

The MAX material may be located in the coating as separate layers in a laminate structure with the at least one other component of the coating, the laminate could have two or more layers. However, it may also be in the form of particles, flakes or the like, in a matrix of the at least one other component of the coating.

In some cases it might be applicable to provide an optional thin bonding layer between the metal substrate and the composite coating in order to further improve the adhesion of the coating. The bonding layer may for example be based on one of the metals from the MAX material, or one of the other components of the composite coating, but also other metallic materials may be used as bonding layer. The bonding layer should according to an embodiment be as thin as possible, not more than 50 nm, preferably not more than 10 nm.

In the case where the substrate is a strip or foil it could for certain applications be useful to have one surface of the substrate coated with the composite material containing MAX material while the other surface is coated with a different material, for example a non-conductive material or a material which will improve soldering, such as Sn or Ni. In these cases the composite coating may be applied to one side of the substrate and for example an electrically isolating material such as Al₂O₃ or SiO₂ may be applied to the other side of the substrate. This may be done in-line with the coating of the composite material in separate chambers, or it may be done at separate occasions.

1: Method of coating of a metal substrate utilising vapour phase deposition technique wherein a composite coating consisting of at least two components wherein at least one has a composition of Mₙ₊₁A_{z}Xₙ, wherein M is at least one metal selected from the group of Ti, Sc, V, Cr, Zr, Nb, Ta; A is at least one element selected from the group consisting of Si, Al, Ge and/or Sn; and X is at least one of the non-metals C and/or N, n is within the range of 0.8-3.2 and z is within the range of 0.8-1.2, is coated onto the surface of the substrate.

2: Method according to claim 1 wherein the coating is performed in a continuous process.

3: Method according to claim 1 wherein the vapour phase deposition technique is magnetron sputtering.

4: Method according to claim 1 wherein the vapour phase deposition technique is electron beam evaporation.

5: Method according to claim 4 wherein the electron beam evaporation is plasma activated and/or reactive.

6: Method according to claim 1 wherein the coating process is performed in a roll to roll process.

7: Method according to claim 1 wherein the substrate is provided in a length of at least 10 meters.

8: Method according to claim 1 wherein a target having the following composition Mₙ₊₁A_{z}Xₙ, wherein M is at least one transition metal selected from the group of Ti, Sc, V, Cr, Zr, Nb, Ta; A is at least one element selected from the group consisting of Si, Al, Ge and/or Sn; and X is at least one of the non-metals C and/or N, wherein n is within the range of 0.8-3.2 and z is within the range of 0.8-1.2 is produced and inserted in at least one coating chamber and thereafter vaporised in order to produce at least a part of the content of Mₙ₊₁A_{z}Xₙ of the composite coating.

9: Method according to claim 1 wherein a bonding layer is provided on the substrate before coating with the composite coating.

10: Method according to claim 1 wherein the composite coating is based on the Mₙ₊₁A_{z}Xₙ component.

11: Method according to claim 1 wherein the composite coating contains maximally 20% of the Mₙ₊₁A_{z}Xₙ component.

12: Coated product consisting of a metal substrate and a composite coating wherein the composite coating consist of at least two components wherein at least one has the composition Mₙ₊₁A_{z}Xₙ, wherein M is at least one transition metal selected from the group of Ti, Sc, V, Cr, Zr, Nb, Ta; A is at least one element selected from the group consisting of Si, Al, Ge and/or Sn; and X is at least one of the non-metals C and/or N, wherein n is within the range of 0.8-3.2 and z is within the range of 0.8-1.2.

13: Coated product according to claim 12 wherein the metal substrate is at least 10 meters long.

14: Coated product according to claim 12 wherein one of the components of the composite coating is metallic, such as Ag, Au, Ni, Cu, Sn, Pt, Mo, Co or an alloy based on any of these elements.

15: Coated product according to claim 12 wherein one of the components of the composite coating is a non-metal such as C.

16: Coated product according to claim 12 wherein one of the components of the composite coating is a carbide, nitride, oxide or any combination thereof.

17: Coated product according to claim 12 wherein a bonding layer is located between the substrate and the coating.

18: Use of a coated product according to claim 12 as electrical contact materials, wear resistant contacts, low friction surfaces, interconnects, implants, decorative surfaces or non-sticking surfaces.
